(19) United States
(12) Patent Application Publication
(10) Pub. No.: US 2024/0052520 A1
(43) Pub. Date: Feb. 15, 2024

(54) SYSTEM AND METHOD OF PRODUCING MONOCRYSTALLINE LAYERS ON A SUBSTRATE

(71) Applicant: KISELKARBID I STOCKHOLM AB, KISTA (SE)

(72) Inventors: Johan Peter EKMAN, Saltsjöbaden (SE); Lin DONG, Spânga (SE); Kassem ALASSAAD, Järfälla (SE)

(73) Assignee: KISELKARBID I STOCKHOLM AB, KISTA (SE)

(21) Appl. No.: 18/549,053

(22) PCT Filed: Feb. 18, 2022
(86) PCT No.: PCT/SE2022/050179

§ 371 Date: Sep. 5, 2023

(30) Foreign Application Priority Data
Mar. 11, 2021 (SE) 2150284-4

(51) Int. Cl. C30B 23/06; C23C 14/50; C23C 14/24; C30B 29/36; C23C 14/06

(52) U.S. Cl. CPC C30B 23/06; C23C 14/50; C23C 14/24; C30B 29/36; C23C 14/0635

(57) ABSTRACT

A system (100) for producing an epitaxial monocrystalline layer on a substrate (20) comprising: an inner container (30) defining a cavity (5) for accommodating a source material (10) and the substrate (20); an insulation container (50) arranged to accommodate the inner container (30) therein; an outer container (60) arranged to accommodate the insulation container (50) and the inner container (30) therein; and heating means (70) arranged outside the outer container (60) and configured to heat the cavity (5), wherein the inner container (30) comprises a plurality of spacer elements (320) arranged to support the substrate (20) at a predetermined distance above a solid monolithic source material (10), wherein each spacer element (320) comprises a base portion (321) and a top portion (322), wherein at least part of the top portion (322) tapers towards an apex (323) arranged to contact the substrate (20). A corresponding method is also disclosed.

### TECHNICAL FIELD

The invention relates generally to growth of monocrystals or monocrystalline layers on a substrate. Specifically, the invention relates to sublimation growth of high-quality monocrystalline layers by using the sublimation sandwich method. More specifically, the invention relates to a new configuration for growth of high-quality monocrystalline layers by using the sublimation sandwich method.

### BACKGROUND ART

In recent years, there has been an increasing demand for the improvement of energy efficiency of electronic devices capable of operation at high power levels and high temperatures. Silicon (Si) is currently the most commonly used semiconductor for power devices. In recent decades, significant progress of the performance of Si-based power electronic devices has been made. However, with Si power device technology maturing, it becomes more and more challenging to achieve innovative breakthroughs using this technology. With a very high thermal conductivity (about 4.9 W/cm), high saturated electron drift velocity (about 2.7×10⁷ cm/s) and high breakdown electric field strength (about 3 MV/cm), silicon carbide (SiC) is a suitable material for high temperature, high voltage and high-power applications.

The most common technique used for the growth of SiC monocrystals is the technique of Physical Vapor Transport (PVT). In this growth technique, the seed crystal and a source material are both placed in a reaction crucible which is heated to the sublimation temperature of the source and in a manner that produces a thermal gradient between the source and the marginally cooler seed crystal. The typical growth temperature is ranging from 2200° C. to 2500° C. The process of crystallization lasts typically for 60-100 hours, SiC monocrystal obtained (herein being named as SiC boule or SiC ingot) during that time has the length of 15-40 mm. After growth, the SiC boule is processed by a series of wafering steps, mainly including slicing, polishing and cleaning processes, until a batch of SiC wafers are produced. The SiC wafers should be usable for being the substrates, on which SiC monocrystalline layer with well controllable doping and several to several tens of micrometers in thickness can be deposited by chemical vapor deposition (CVD).

The sublimation sandwich method (SSM) is another variant of the physical vapor transport (PVT) growth. Instead of a SiC powder as source material, the source is a monolithic SiC plate of either mono- or polycrystalline structure, which is very beneficial for controlling the temperature uniformity. The distance between the source and the substrate is short for direct molecular transport (DMT), typically 1 mm, which has the positive effect that the vapor species do not react with the graphite walls. The typical growth temperature of SSM is about 2000° C., which is lower than that of PVT. Such lower temperature can help obtain higher crystal quality of SiC monocrystals or monocrystalline layers than that in PVT case. During the growth, the growth pressure is kept at vacuum condition, around 1 mbar, in order to achieve high growth rate, around 150 μm/h. Since the thickness of the source is typically 0.5 mm, the grown SiC layer has about the same thickness, which is thinner than that of PVT grown boules which typically are 15-50 mm long. Therefore, the obtained sample using SSM can be regarded as either a SiC mini-boule from the perspective of bulk growth or a super-thick SiC epitaxial layer from the perspective of epitaxy.

In SSM, a source and a seed are loaded in a carbon crucible, so that a small gap between the source and seed is formed. As revealed in the paper “Effect of Tantalum in Crystal Growth of Silicon Carbide by Sublimation Close Space Technique”, Furusho et al., Jpn. J. Appl. Phys. Vol. 40 (2001) pp. 6737-6740 and U.S. Pat. No. 7,918,937 B2, the seed is loaded above the source, with the support of a spacer in the middle. In the prior art, for example, as shown in FIGS. 1 and 2, the shape of the spacer is usually ring-like, with an inner cutout of either square shape or circular shape, depending on the sample. The disadvantage of this shape is the full coverage of the sample edge, leading to significant loss of material usage area.

Another problem encountered when producing epitaxial layers on a substrate is the formation of defects and associated prismatic stacking faults propagating into the epitaxial layer in the grown surface. Surface morphological defects are generally classified in accordance with their physical appearance. Thus, such defects have been classified as “comet”, “carrot” and “triangular” defects based on their appearance under a microscope. Carrot defects are roughly carrot-shaped features in the surface of the silicon carbide film. The features are aligned along the step flow direction of the film and are characteristically longer than the depth of the layer in which they are formed. The presence of such crystalline defects in silicon carbide films may degrade the performance of or even totally destroy electronic devices fabricated in the films, depending on the type, location, and density of the defects. The ring-like shape of the spacer mentioned above also brings about the higher probability of the formation of the above-mentioned crystalline defects originating from the ring edge especially at the upstream side, since the growth may be disturbed by the spacer contacted with the substrate edge.

An additional disadvantage of the use of the ring-like shape of the spacer is that the substrate backside at the edge area contacted with the spacer may have higher sublimation rate than the area not contacting the spacer. Such non-uniform backside sublimation of the substrate results in the unwanted material loss at the substrate edge and increases the total thickness of the finished substrate in a non-uniform manner.

Thus, there is a need to improve the known systems and methods to overcome the deficiencies and disadvantages mentioned above.

### SUMMARY OF INVENTION

With the foregoing and other objects in view there is provided, in accordance with a first aspect of the present disclosure, a system for producing an epitaxial monocrystalline layer on a substrate comprising: an inner container defining a cavity for accommodating a source material and the substrate; an insulation container arranged to accommodate the inner container therein; an outer container arranged to accommodate the insulation container and the inner container therein; and heating means arranged outside the outer container and configured to heat the cavity, wherein the inner container comprises a plurality of spacer elements arranged to support the substrate at a predetermined distance above a solid monolithic source material, wherein each spacer element comprises a base portion and a top portion, wherein at least part of the top portion tapers towards an apex arranged to contact the substrate.

The at least partially tapering spacer elements towards an apex or point minimizes the contact surface with the substrate. It has been found that this not only increases the available growth surface on the substrate, but also reduces the formation of crystalline defects in the grown surface since the contact area between spacer and substrate giving rise to such defect formation is minimized. For the same reason, non-uniform backside sublimation is also reduced.

In one embodiment, the top portion tapers from the base portion to the apex. With a shape tapering along the whole extension of spacer element, the manufacturing process is facilitated, e.g. through laser cutting to achieve optimal spacer elements. Preferably, the spacer elements have a shape chosen from a pyramid, a cone, a tetrahedron and a prism.

In one embodiment, each spacer element has a height, and the base portion has a transverse width, wherein the ratio between the height and the transverse width is from 1:3 to 3:1. Preferably, the height of each spacer element is about 0.7-1.4 mm and the transverse width is smaller than or equal to 2.5 mm. the chosen range ensures optimal stability and spacing between the source and the substrate.

In one embodiment, a ratio between a surface area of the apex and a surface area of the base portion is from 1:1000 to 1:5. Preferably, the surface area of the apex is about 100 μm².

In one embodiment, the spacer elements are regularly distributed about the circumference of the substrate.

In one embodiment, the spacer elements are made of tantalum, niobium, tungsten, hafnium, silicon carbide, graphite and/or rhenium. The material chosen ideally withstands the high temperatures without deformation and without reacting with or otherwise affecting the growth of the epitaxial layer on the substrate.

In one embodiment, the inner container is cylindrical having an inner diameter in the range 100-500 mm, preferably 150-300 mm, and wherein the substrate and the source material are disk-shaped. The cylindrical shape facilitates optimal temperature distribution in the cavity and over the source and substrate and the range corresponds to standard wafer sizes in semiconductor devices.

In one embodiment, the system further comprises a heating body made of high-density graphite arranged below the inner container. The heating body allows for coupling with the heating means to provide improved heating and optimal temperature distribution in the cavity.

In one embodiment, the surface area of the source material is greater than or equal to the surface area of the substrate. The greater or equal surface area of the source ensures optimal exposure of the entire growth surface of the substrate and facilitates positioning of the spacer elements on the source material.

In one embodiment, the system further comprises a carbon getter arranged in the inner container.

In a second aspect of the present disclosure, there is provided a method of producing an epitaxial monocrystalline layer on a substrate comprising:
providing an inner container defining a cavity for accommodating a source material and the substrate;
arranging a solid monolithic source material in the cavity;
arranging the substrate at a predetermined distance above source material by using a plurality of spacer elements, wherein each spacer element comprises a base portion and a top portion, wherein at least part of the top portion tapers towards an apex, arranged to contact the substrate;
arranging the inner container within an insulation container;
arranging the insulation container and the inner container an outer container;
providing heating means outside the outer container to heat the cavity;
evacuating the cavity to a predetermined low pressure;
introducing an inert gas into the cavity;
raising the temperature in the cavity to a predetermined growth temperature by the heating means;
maintaining the predetermined growth temperature in the cavity until a predetermined thickness of the epitaxial monocrystalline silicon carbide layer on the substrate has been achieved; and
cooling the substrate.

In one embodiment, the spacer elements are regularly distributed about the circumference of the substrate.

### BRIEF DESCRIPTION OF DRAWINGS

The invention is now described, by way of example, with reference to the accompanying drawings, in which:

FIGS. 1 and 2 show a schematic illustrations of spacer configurations known from prior art;

FIG. 3 shows a schematic cross-sectional view of a system for producing an epitaxial monocrystalline layer on a substrate according to one embodiment of the present disclosure;

FIG. 4 shows a schematic cross-sectional view of an inner container with a source material and a substrate arranged therein according to one embodiment of the present disclosure;

FIG. 5 shows a schematic illustration of a spacer element according to one embodiment of the present disclosure;

FIG. 6 shows a schematic illustration of an arrangement of spacer elements according to one embodiment of the present disclosure;

FIG. 7 shows a diagram of temperature versus time during the growth process;

FIG. 8 shows a flow chart illustrating steps of a method according to one embodiment of the present disclosure;

FIG. 9 shows the appearance of a grown SiC sample produced in accordance with the present disclosure; and

FIGS. 10a and 10b illustrate the crystal quality evaluation using Raman spectroscopy and X-ray diffraction (XRD) spectroscopy for a 1.5 mm thick 4H-SiC monocrystalline epitaxial layer with 150 mm in diameter, manufactured in accordance with the present disclosure.

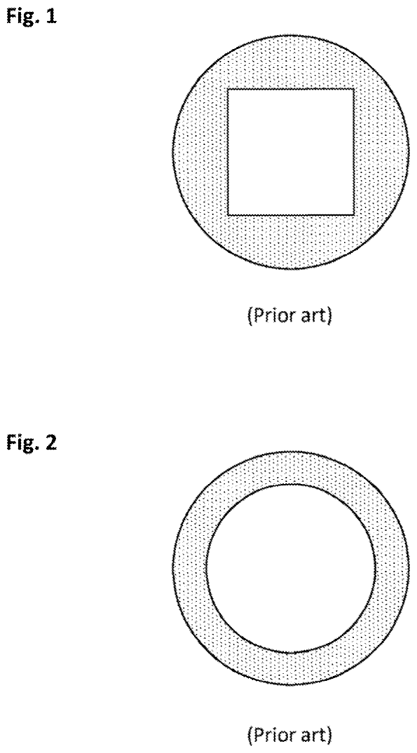

### DESCRIPTION OF EMBODIMENTS

In the following, a detailed description of a system for producing an epitaxial monocrystalline layer on a substrate according to the present disclosure is presented. In the drawing figures, like reference numerals designate identical or corresponding elements throughout the several figures. It will be appreciated that these figures are for illustration only and are not in any way restricting the scope of the invention.

One objective of the present invention is to provide a new type of spacers in SSM which can realize the growth nearly on the entire seed, whilst minimizing the occupation area of the spacers on the seed surface. The spacers are made of tantalum with a pyramidal, cylindrical or conical shape and a small size (<2.5 mm in the base and 0.7-1.4 mm height). In practical, three of such spacers are loaded on the source surface, and the seed is loaded on the spacers.

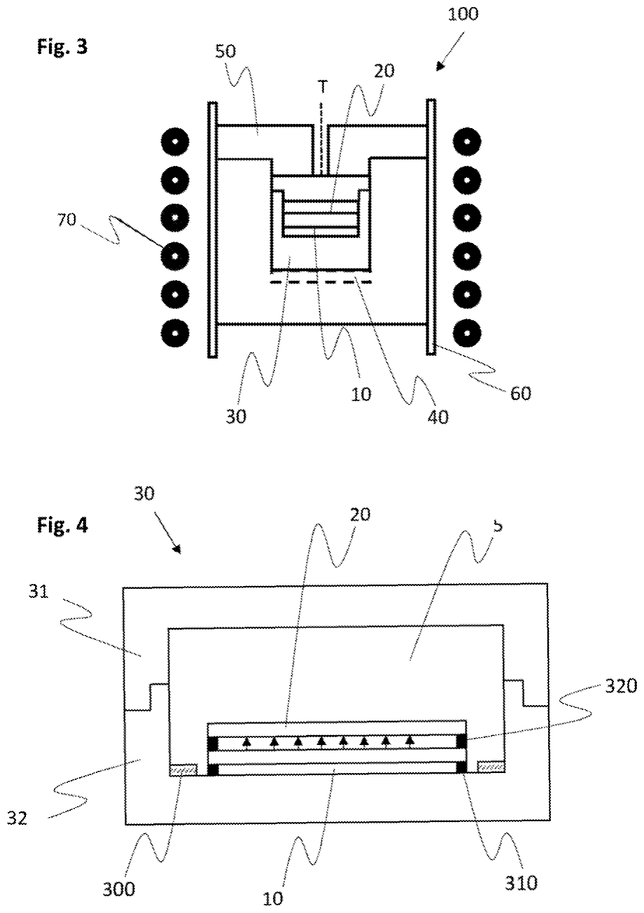

FIG. 3 is a schematic illustration of the system 100 designed to facilitate sublimation epitaxy using the above mentioned polycrystal SiC plate as the source material 10, which enables the growth of a monocrystal or monocrystalline SiC layer. The source material 10 and the substrate 20 are arranged in a cavity of an inner container 30 in a face-down configuration, i.e., with the substrate 20 arranged above the source material 10. The inner container 30 is arranged within an insulation container 50, which insulation container 50 in turn is arranged in an outer container 60. The inner container 30 may be supported on container supports (not shown) which in turn are on the top of a bottom part of insulation container 50. A heating body 40 may optionally be arranged below the inner container 30. Outside said outer container 60 there are heating means 70, which can be used to heat the cavity of said inner container 30.

According to one embodiment the heating means 70 comprises an induction coil for radiofrequency heating. Said outer container 60 is in this example a quartz tube and said insulation container 50 and said inner container 30 are cylindrical and made of an insulating graphite foam and high-density graphite, respectively. The heating means 70 is used to heat the container and by this sublime the source material 10. The heating means 70 is movable in a vertical direction in order to adjust the temperature and thermal gradient in the inner container 30. The temperature gradient between the source material 10 and substrate 20 can also be altered by varying the properties of the inner container 30, such as the thicknesses of the upper part 31 and the lower part 32 (see FIG. 4) as is known in the art. Additionally, there are pumps for evacuating the inner container (not shown), i.e. to provide a pressure between about 10⁻⁴ and 10⁻⁶ mbar.

FIG. 4 is a schematic illustration of a preferred arrangement of components 10, 20, 300, 310, 320 within the cavity 5 of the inner container 30. A substrate 20 is supported by spacer elements 320 and is arranged above source material 10, which is supported by source supports 310. The diameter of the source material 10 should be equal to or larger than that of the substrate 20. For example, if the substrate 20 has a diameter of 150 mm, the source material 10 should have at least 150 mm, preferably 160 mm in diameter. Close to the source material 10, a carbon getter 300 is loaded on the inner bottom of the inner container 30. The spacer elements 320, the source support 310 and the carbon getter 300 can be made of a material having a melting point higher than 2200° C. and having an ability of forming a carbide layer with carbon species evaporated from the source material, such as tantalum, niobium and tungsten.

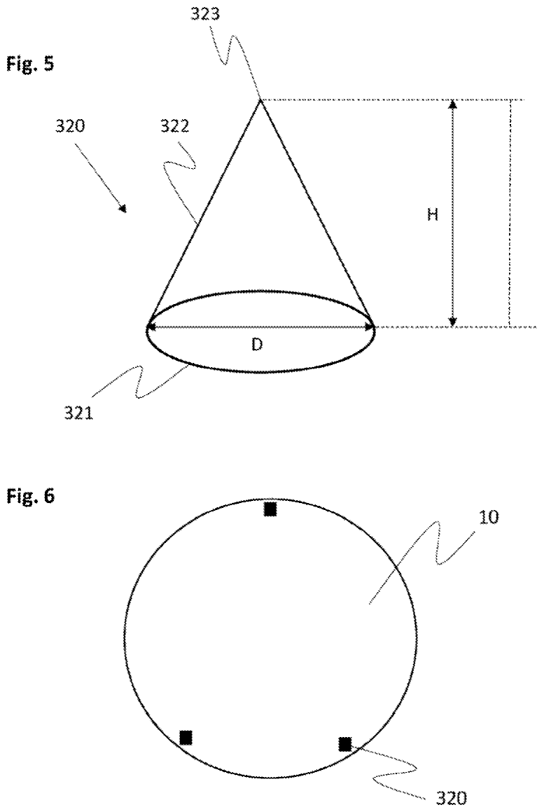

The substrate support preferably comprises three spacer elements 320, each of which having identical shapes. However, substrate supports with different shapes or numbers of spacer elements 320 are also contemplated. Referring now to FIG. 5, there is shown an embodiment of a spacer element 320 according to the present disclosure. The spacer element 320 comprises a base portion 321 and a top portion 322 extending upwardly from the base portion 321. In order to minimize the contact area with the substrate surface, at least part of the top portion 322 of the spacer element 320 tapers towards a tip or apex 323. Preferably, the spacer element 320 tapers from the base portion 321 to the apex 323, simplifying the manufacturing process. The preferred shape of the spacer element 320 is a pyramid, a cone (shown in FIG. 5), a tetrahedron or a prism. In the case of a prism, the apex is understood as the highest edge located opposite the base portion. The transverse width or diameter D of the base portion 321 is preferably 2.5 mm, and the height H of the spacer is preferably 1 mm, giving a ratio of the height H to the transverse width D of 1:2. However, the ratio H:D may be in the range 3:1 to 1:3.

In order to minimize the contact surface between the apex 323 of the spacer elements 320 and the substrate 20, the spacer elements are manufactured by laser cutting. With this process, a surface area of the apex 323 of about 10 μm by 10 μm, i.e., about 100 μm² has been achieved. Preferably, the ratio between the surface areas of the apex 323 and the base portion 321 is between 1:1000 and 1:5.

FIG. 6 shows an example of the arrangement of three spacer elements 320 on the top of the source material 10. To support the substrate 20 stably, the three spacer elements 320 are preferably distributed regularly around the circumference of the source material 10 and the substrate 20, e.g., arranged in a manner of forming an equilateral triangular configuration.

The source material 10 is lifted by the source support 310 to form a gap between the source material 10 and the bottom of the inner container 30. This can help improve the temperature uniformity of the source material 10 by avoiding the non-uniform contact between the source material 10 and the bottom of the inner container 30. The man skilled in the art should know that the source support 310 is not limited to any special shape, for example, it can be as identical as the ones shown in FIG. 5. It should be noted that the requirement of the source support 310 should be as small as possible in volume, without the special requirement of the contact area size with the source material 10. By comparison, the spacer elements 320 preferably has not only a minimum volume but also a sharp end at the apex 323 for the purpose of minimizing the contact area with the substrate 20.

As mentioned above, the substrate 20 is to be arranged above the source material 10 on the spacer elements 320. To achieve this, the source material 10 is a solid monolithic plate, sufficiently rigid to enable placement of the spacer elements 320 on the source material 10 to support the substrate 20 along a peripheral edge thereof. In one embodiment, the source material 10 is a monolithic SiC plate to produce an epitaxial monocrystalline SiC layer on the substrate 20 through SSM. However, other source materials may also be used in conjunction with the system 100 and method of the present disclosure depending on the desired epitaxial layer to be produced, such as e.g., aluminum nitride (AlN).

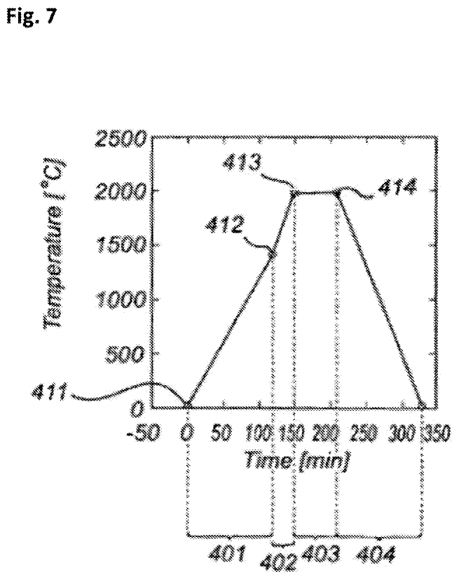

The method will now be described with reference to a system design as described above, but the man skilled in the art knows that the design is only an example and that other designs can also be used as long as the desired growth conditions are achieved. FIG. 7 schematically illustrates the temperature variation at the substrate during the epitaxial sublimation. The growth process comprises a pre-heating phase 401 wherein the system is set up for example in accordance with the above description, and the inner container is evacuated using conventional pumping means. A base vacuum level of lower than 10⁻⁴ mbar is normally desired. After that, an inert gas like argon is introduced into the reactor chamber and the chamber pressure is kept at about 2 mbar. Then, the whole growth system is heated up by heating means in the form of radiofrequency (RF) coils to the growth temperature.

The inventors have discovered that the increase of the temperature is preferably between 10-50° C./min, and more preferably about 20-30° C./min. Such a temperature increase provides a good initial sublimation of the source and nucleation. The temperature is raised during the heating phase 402 until a desired growth temperature 413 in the range 1900-2000° C. is reached, typically about 1950° C. When a suitable growth temperature 413 has been reached, i.e., a growth temperature which facilitates a desired growth rate, the temperature increase is quickly decreased. The man skilled in the art knows at which temperatures a desired growth rate is obtained. The temperature is kept at this level 413, until an epitaxial layer of desired thickness has been achieved. The period following the heating phase is referred to as the growth phase 403, during this phase the temperature is preferably kept substantially constant.

When a desirably thick monocrystalline layer has been produced 414, the heating is turned off and the substrate is allowed to cool down, this is referred to as the cooling phase 404. The pre-heating and the cooling phase can be optimized in order to decrease the production time.

In the context of the invention the thickness of the grown monocrystalline layer is more than 5 μm, or more preferably thicker than 100 μm, and most preferably thicker than 500 μm. The maximum thickness of the grown crystal is determined by the thickness of the source material 10.

The method will now be described with reference to a system design as described above, but the man skilled in the art knows that the design is only an example and that other designs can also be used as long as the desired growth conditions are achieved.

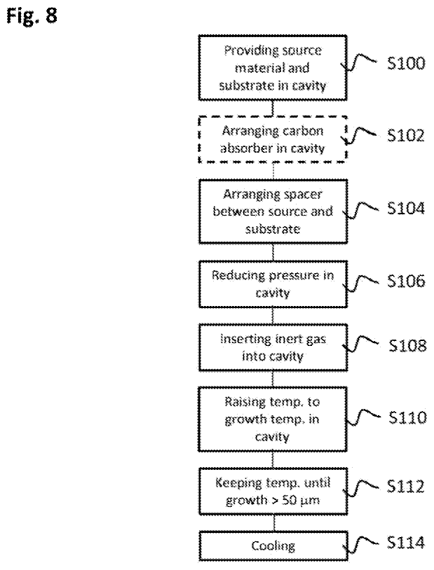

FIG. 8 illustrates the process flow in this method. In a first step S100, the source material 10 and substrate 20 are provided in the cavity 5 of the inner container 30. Optionally, in step S102 the carbon getter 300 is arranged in the cavity. Subsequently, the spacer elements 320 are arranged between the source material 10 and the substrate 20. The growth process comprises a pre-heating phase S106 wherein the system 100 is evacuated using conventional pumping means. A base vacuum level of lower than 10⁻⁴ mbar is normally desired, preferably between 10⁻⁴ and 10⁻⁶ mbar. After that, an inert gas, preferably argon (Ar), is inserted into the cavity 5 to obtain a pressure lower than 950 mbar, preferably 600 mbar (S108). The system is then heated up (S110). The inventors have discovered that the optimal increase of the temperature is preferably in the range 10-50° C./min, and more preferably about 20-30° C./min. Such a temperature increase provides a good initial sublimation of the source and nucleation. The temperature is raised until a desired growth temperature in the range 1900-2000° C. is reached, typically about 1950° C. When a suitable growth temperature has been reached, i.e., a growth temperature which facilitates a desired growth rate, the pressure is slowly decreased to the growth pressure. The man skilled in the art knows at which temperatures a desired growth rate is obtained. The temperature is kept at this growth temperature, until an epitaxial layer of desired thickness has been achieved. The period following the heating phase is referred to as the growth phase S104, during this phase the temperature is preferably kept substantially constant. In one embodiment, the thickness of the epitaxial layer obtained in the growth phase S104 is 1500 μm.

When a desirably thick monocrystalline layer has been produced the heating is turned off and the substrate is allowed to cool, this is referred to as the cooling phase S114. The pre-heating and the cooling phase can be optimized in order to decrease the production time.

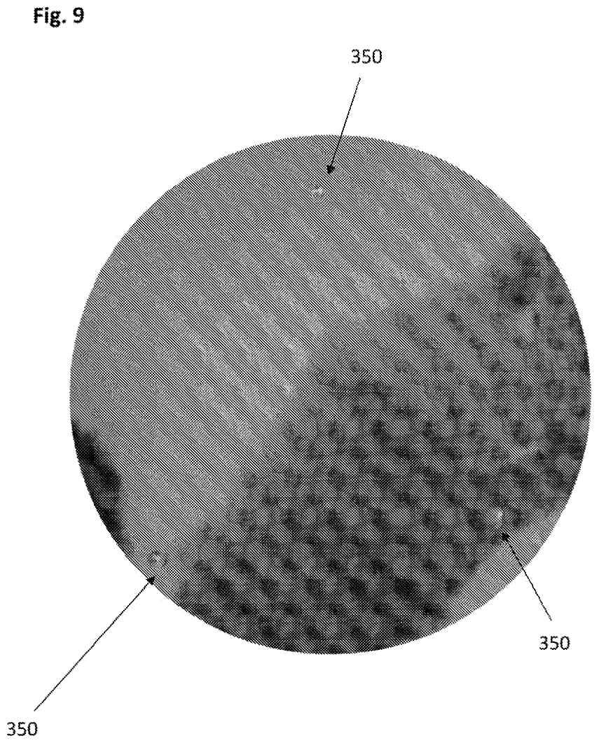

FIG. 9 shows the appearance images of grown SiC samples using the method according to the present disclosure. A 1.5 mm thick 4H-SiC monocrystalline layer has been grown on the 150 mm substrate surface. On the sample surface, only three marks (dents) 350 related to the spacer elements 320 can be found. The size is about 3 mm, slightly larger than the base of the base D of the spacer (2.5 mm). No other morphological defects around the marks 350 are triggered.

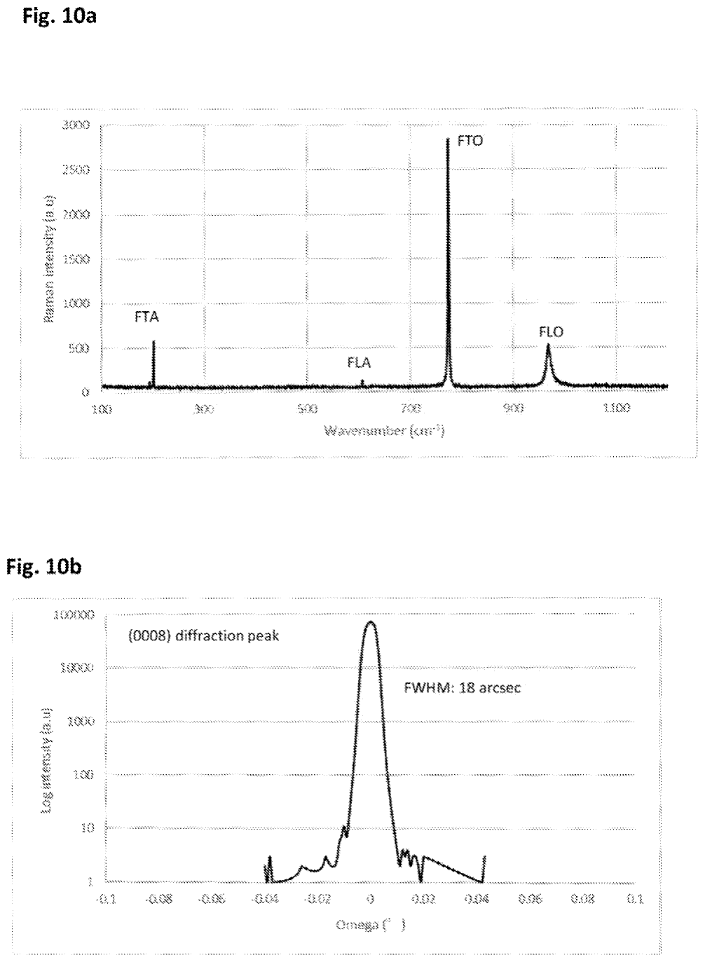

FIGS. 10a and 10b illustrate the crystal quality evaluation using Raman spectroscopy and X-ray diffraction (XRD) spectroscopy for a 1.5 mm thick 4H-SiC monocrystalline epitaxial layer with 150 mm in diameter, manufactured according to the inventive method. FIG. 10a shows the Raman peaks with wavenumbers of 204 cm⁻¹, 610 cm⁻¹, 776 cm⁻¹ and 968 cm⁻¹, which correspond to Folded Transversal Acoustic (FTA), Folded Longitudinal Acoustic (FLA), Folded Transversal Optical (FTO), and Folded Longitudinal Optical (FLO) peaks of 4H-SiC. FIG. 10b shows the XRD rocking curve of (0008) plane for this sample. The full width at half maximum (FWHM) value is about 18 arc second, which indicates a high quality of 4H-SiC monocrystal.

Although the present disclosure has been described in detail in connection with the discussed embodiments, various modifications may be made by one of ordinary skill in the art within the scope of the appended claims without departing from the inventive idea of the present disclosure. Further, the method can be used to produce more than one layer in the same cavity as is readily realized by the man skilled in the art.

All the described alternative embodiments above or parts of an embodiment can be freely combined without departing from the inventive idea as long as the combination is not contradictory.

1-15. (canceled)

16. A system for producing an epitaxial monocrystalline layer on a substrate comprising:
an inner container defining a cavity for accommodating a source material and the substrate;
an insulation container arranged to accommodate the inner container therein;
an outer container arranged to accommodate the insulation container and the inner container therein; and
heating means arranged outside the outer container and configured to heat the cavity,
wherein the inner container comprises a plurality of spacer elements arranged to support the substrate at a predetermined distance above a solid monolithic source material, wherein each spacer element comprises a base portion and a top portion, wherein at least part of the top portion tapers towards an apex arranged to contact the substrate.

17. The system according to claim 16, wherein the top portion tapers from the base portion to the apex.

18. The system according to claim 17, wherein the spacer elements have a shape chosen from a pyramid, a cone, a tetrahedron and a prism.

19. The system according to claim 16, wherein each spacer element has a height (H), and the base portion has a transverse width (D), wherein the ratio between the height (H) and the transverse width (D) is from 1:3 to 3:1.

20. The system according to claim 19, wherein the height (H) of each spacer element is about 0.7-1.4 mm and the transverse width (D) is smaller than or equal to 2.5 mm.

21. The system according to claim 16, wherein a ratio between a surface area of the apex and a surface area of the base portion is from 1:1000 to 1:5.

22. The system according to claim 21, wherein the surface area of the apex is about 100 μm².

23. The system according to claim 16, wherein the spacer elements are regularly distributed about the circumference of the substrate.

24. The system according to claim 16, wherein the spacer elements are made of tantalum, niobium, tungsten, hafnium, silicon carbide, graphite and/or rhenium.

25. The system according to claim 16, wherein the inner container is cylindrical having an inner diameter in the range 100-500 mm, preferably 150-300 mm, and wherein the substrate and the source material are disk-shaped.

26. The system according to claim 16, further comprising a heating body made of high-density graphite arranged below the inner container.

27. The system according to claim 16, wherein the surface area of the source material (10) is greater than or equal to the surface area of the substrate.

28. The system according to claim 16, further comprising a carbon getter arranged in the inner container.

29. A method of producing an epitaxial monocrystalline layer on a substrate comprising:
providing (S100) an inner container defining a cavity for accommodating a source material and the substrate;
arranging a solid monolithic source material in the cavity;
arranging (S104) the substrate at a predetermined distance above the source material by using a plurality of spacer elements, wherein each spacer element comprises a base portion and a top portion, wherein at least part of the top portion tapers towards an apex, arranged to contact the substrate;
arranging the inner container within an insulation container;
arranging the insulation container and the inner container an outer container;
providing heating means outside the outer container to heat the cavity;
evacuating (S106) the cavity to a predetermined low pressure;
introducing (S108) an inert gas into the cavity;
raising (S110) the temperature in the cavity to a predetermined growth temperature by the heating means;
maintaining (S112) the predetermined growth temperature in the cavity until a predetermined thickness of the epitaxial monocrystalline silicon carbide layer on the substrate has been achieved; and
cooling (S114) the substrate.

30. The method according to claim 29, wherein the spacer elements are regularly distributed about the circumference of the substrate.
